(19) United States
(12) Patent Application Publication
(10) Pub. No.: US 2017/0169879 A1
(43) Pub. Date: Jun. 15, 2017

(54) SEMICONDUCTOR DEVICES AND SEMICONDUCTOR SYSTEMS INCLUDING THE SAME

(71) Applicant: SK hynix Inc., Icheon-si (KR)

(72) Inventors: YongWoo LEE, Seongnam-si (KR); Jae Jin LEE, Gwangju-si (KR); HoeKwon JEONG, Icheon-si (KR)

(21) Appl. No.: 15/080,904

(22) Filed: Mar. 25, 2016

(30) Foreign Application Priority Data
Dec. 9, 2015 (KR) 10-2015-0175457

(51) Int. Cl. G11C 11/406; G11C 11/408; G11C 11/4093; G11C 11/4091

(52) U.S. Cl. CPC G11C 11/40611; G11C 11/4091; G11C 11/4085; G11C 11/4087; G11C 11/4093

(57) ABSTRACT

A semiconductor system includes a semiconductor device. The semiconductor device executes an active operation according to a combination of command/address signals to store location information of mats selectively activated. In addition, the semiconductor device enters a refresh operation according to a combination of the command/address signals to selectively activate the mats included in a memory part according to the location information stored in the semiconductor device in response to a mat control signal.

### CROSS-REFERENCE TO RELATED APPLICATIONS

The present application claims priority under 35 U.S.C §119(a) to Korean Patent Application No. 10-2015-0175457, filed on Dec. 9, 2015, which is herein incorporated by reference in its entirety.

### BACKGROUND

1. Technical Field

Embodiments of the present disclosure relate to semiconductor devices executing a refresh operation by activating a word line and semiconductor systems including the same.

2. Related Art

Dynamic random access memory (DRAM) devices, among semiconductor devices, may lose data stored in memory cells as the time elapses even when power is maintained to the device, in contrast to static random access memory (SRAM) devices or flash memory devices. In order to prevent data stored in the DRAM cells from being lost, DRAM devices may have an operation for rewriting the data from external systems in a certain period, which is called “a refresh operation”. Usually, such a refresh operation is carried out during retention times that are inherent to memory cells having mats. The refresh operation may be carried out by activating word lines at least one or more times, and sensing/amplifying data of the memory cells. The retention time is a time for which data can be maintained without a refresh operation after being written into a memory cell.

The refresh operation may be categorized as either an auto-refresh operation or a self-refresh operation. The auto-refresh operation may be executed by refresh commands outputted from a controller that controls the DRAM devices, and the self-refresh operation may be executed by self-refresh signals which are internally generated in the DRAM devices.

### BRIEF DESCRIPTION OF THE DRAWINGS

FIG. 1 is a block diagram illustrating a semiconductor system according to an embodiment.

FIG. 2 is a circuit diagram illustrating a control circuit included in the semiconductor system of FIG. 1.

FIG. 3 is a block diagram illustrating a first memory part included in the semiconductor system of FIG. 1.

FIG. 4 is a circuit diagram illustrating a first main word line driver included in the first memory part of FIG. 3.

FIG. 5 is a circuit diagram illustrating a first drive signal generator included in the first memory part of FIG. 3.

FIG. 6 is a circuit diagram illustrating a first sub-word line driver included in the first memory part of FIG. 3.

FIG. 7 is a timing diagram illustrating an operation of a semiconductor system according to an embodiment.

FIGS. 8, 9, and 10 are schematic diagrams illustrating operations of a semiconductor system according to an embodiment.

FIG. 11 is a block diagram illustrating a configuration of an electronic system including the semiconductor device or the semiconductor system shown in FIGS. 1 to 10.

### DETAILED DESCRIPTION

Various embodiments are directed to semiconductor memory devices and semiconductor systems including the same.

According to an embodiment, a semiconductor system includes a semiconductor device. The semiconductor device executes an active operation according to a combination of command/address signals to store location information of mats selectively activated. In addition, the semiconductor device executes a refresh operation according to a combination of the command/address signals to selectively activate the mats included in a memory part according to the location information stored in the semiconductor device in response to a mat control signal.

According to another embodiment, a semiconductor device includes a command decoder, an address decoder, a control circuit and an internal circuit. The command decoder decodes command/address signals to generate an active signal enabled to execute an active operation and to generate an auto-refresh signal and an internal refresh signal enabled to execute a refresh operation. The address decoder decodes the command/address signals to generate a row address, a column address and an internal address. The control circuit receives the row address and the column address to store location information therein in response to the active signal or the internal refresh signal. In addition, the control circuit generates a mat selection signal from the location information. Moreover, the control circuit outputs the column address as the mat selection signal in response to the auto-refresh signal and the row address. The internal circuit includes a first memory part and a second memory part, one of which is selectively activated in response to a mat control signal and the mat selection signal.

Various embodiments of the present disclosure will be described hereinafter with reference to the accompanying drawings. However, the embodiments described herein are for illustrative purposes only and are not intended to limit the scope of the present disclosure.

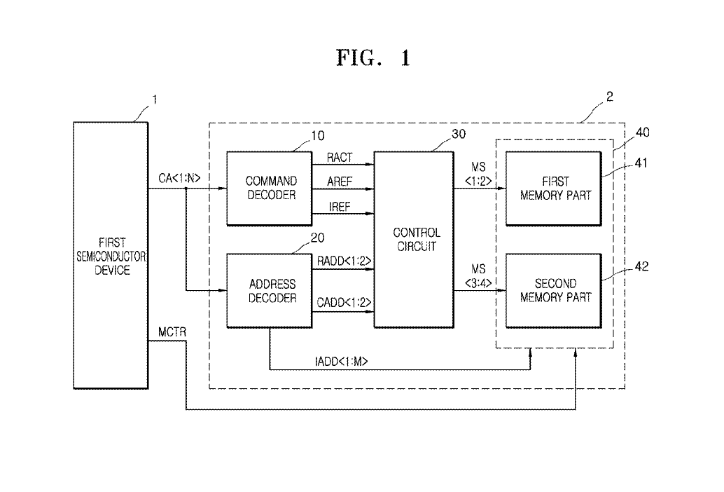

Referring to FIG. 1, a semiconductor system according to an embodiment may include a first semiconductor device 1 and a second semiconductor device 2. The second semiconductor device 2 may include a command decoder 10, an address decoder 20, a control circuit 30, and an internal circuit 40.

The first semiconductor device 1 may output first to N^{th} command and address (command/address) signals CA<1:N> and a mat control signal MCTR. The first to N^{th} command/address signals CA<1:N> may be transmitted through lines that transmit at least one group of addresses, commands, and data. Alternatively, the first to N^{th} command/address signals CA<1:N> may be continuously transmitted through one line. The number of bits of the first to N^{th} command/address signals CA<1:N> may be set differently according to embodiments. A number “N” of the first to N^{th} command/address signals CA<1:N> may correspond to a natural number which is equal to or greater than two.

The command decoder 10 may decode the first to N^{th} command/address signals CA<1:N> to generate an active signal RACT, an auto-refresh signal AREF, and an internal refresh signal IREF. The active signal RACT may be enabled to execute an active operation according to a combination of the first to N^{th} command/address signals CA<1:N>. The auto-refresh signal AREF may be enabled to execute an auto-refresh operation according to a combination of the first to N^{th} command/address signals CA<1:N>. The internal refresh signal IREF may be periodically enabled to execute a self-refresh operation according to a combination of the first to N^{th} command/address signals CA<1:N>.

The address decoder 20 may decode the first to N^{th} command/address signals CA<1:N> to generate first and second row addresses RADD<1:2>, first and second column addresses CADD<1:2>, and first to M^{th} internal addresses IADD<1:M>. The address decoder 20 may decode some bits of the first to N^{th} command/address signals CA<1:N> to generate the first and second row addresses RADD<1:2>, the first and second column addresses CADD<1:2>, and the first to M^{th} internal addresses IADD<1:M>. The number of bits of the first to N^{th} command/address signals CA<1:N> for generating the first and second row addresses RADD<1:2>, the first and second column addresses CADD<1:2>, and the first to M^{th} internal addresses IADD<1:M> may be set to be different according to embodiments. A number “M” of the first to M^{th} internal addresses IADD<1:M> may correspond to a natural number which is equal to or greater than two.

During an active operation, the control circuit 30 may store information on locations of word lines selected by the first and second row addresses RADD<1:2> and the first and second column addresses CADD<1:2> in response to an active signal RACT or an internal refresh signal IREF. Also during an active operation, the control circuit 30 may generate first to fourth mat selection signals MS<1:4> according to the first and second row addresses RADD<1:2> and the first and second column addresses CADD<1:2>. During the self-refresh operation, the control circuit 30 may generate the first to fourth mat selection signals MS<1:4> using location information of the word lines that is stored therein. During the auto-refresh operation, the control circuit 30 may generate the first to fourth mat selection signals MS<1:4> according to the first and second row addresses RADD<1:2> and/or the first and second column addresses CADD<1:2>.

The internal circuit 40 may include a first memory part or first memory circuit 41 and a second memory part or second memory circuit 42. The first memory part 41 may include a plurality of mats, one of which is selectively activated in response to the mat control signal MCTR and the first and second mat selection signals MS<1:2>. The second memory part 42 may include a plurality of mats, one of which is selectively activated in response to the mat control signal MCTR and the third and fourth mat selection signals MS<3:4>.

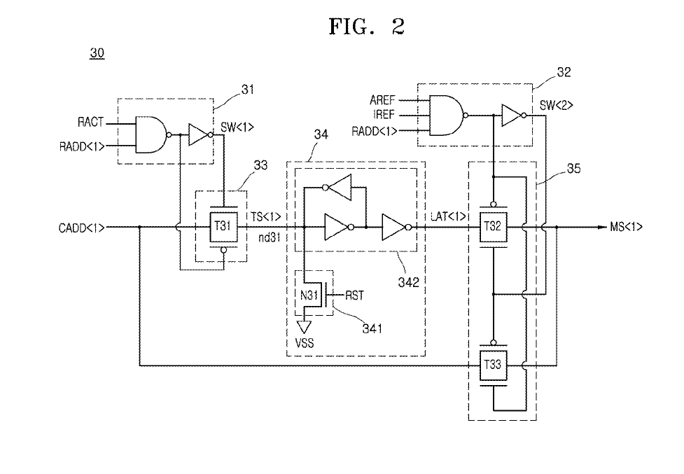

Referring to FIG. 2, the control circuit 30 may include a first switch signal generator 31, a second switch signal generator 32, a first transfer circuit 33, a latch signal generator 34, and a second transfer circuit 35.

The first switch signal generator 31 may generate a first switch signal SW<1> which is enabled if the first row address RADD<1> is generated during the active operation. The first switch signal generator 31 may execute an AND operation of the active signal RACT and the first row address RADD<1> to generate the first switch signal SW<1>. The first switch signal generator 31 may generate the first switch signal SW<1> which is enabled to have a logic “high” level if the active signal RACT has a logic “high” level and the first row address RADD<1> has a logic “high” level.

The second switch signal generator 32 may generate a second switch signal SW<2> which is disabled to have a logic “low” level during the active operation. The second switch signal generator 32 may generate the second switch signal SW<2> which is enabled to have a logic “high” level if the first row address RADD<1> is generated during the self-refresh operation. The second switch signal generator 32 may generate the second switch signal SW<2> which is disabled to have a logic “low” level during the auto-refresh operation. The second switch signal generator 32 may execute an AND operation of the auto-refresh signal AREF, the internal refresh signal IREF, and the first row address RADD<1> to generate the second switch signal SW<2>. The second switch signal generator 32 may generate the second switch signal SW<2> which is disabled to have a logic “low” level in response to the auto-refresh signal AREF having a logic “high” level and the internal refresh signal IREF having a logic “low” level during the active operation. The second switch signal generator 32 may generate the second switch signal SW<2> which is enabled to have a logic “high” level, in response to the auto-refresh signal AREF having a logic “high” level, the internal refresh signal IREF having a logic “high” level, and the first row address RADD<1> having a logic “high” level during the self-refresh operation. The second switch signal generator 32 may generate the second switch signal SW<2> which is disabled to have a logic “low” level in response to the auto-refresh signal AREF having a logic “low” level during the auto-refresh operation.

The first transfer circuit 33 may be realized using a transfer gate T31 and may receive the first column address CADD<1> to generate a first transmission signal TS<1> to the node ND31 if the first switch signal SW<1> is enabled to have a logic “high” level. The first transfer circuit 33 may output the first column address CADD<1> as the first transmission signal TS<1> when the first switch signal SW<1> is enabled to have a logic “high” level.

The latch signal generator 34 may include an initialization circuit 341 and a latch circuit 342.

The initialization circuit 341 may be realized using an NMOS transistor N31 coupled between the node ND31 and a ground voltage VSS terminal. The initialization circuit 341 may drive the node ND31 to the ground voltage VSS if a reset signal RST is enabled to have a logic “high” level. The reset signal RST may be enabled to have a logic “high” level during an initialization operation that the semiconductor system starts to operate.

The latch circuit 342 may buffer the first transmission signal TS<1> to generate and store a first latch signal LAT<1>, where the first column address CADD<1> was stored as the first latch signal LAT<1>.

The second transfer circuit 35 may include transfer gates T32 and T33. The second transfer circuit 35 may output the first latch signal LAT<1> as the first mat selection signal MS<1> through the transfer gate T32 which is turned on if the second switch signal SW<2> is enabled to have a logic “high” level. The second transfer circuit 35 may output the first column address CADD<1> as the first mat selection signal MS<1> through the transfer gate T33 in response to the active signal RACT and the first row address RADD<1>, where the second transfer gate T33 is turned on if the second switch signal SW<2> is disabled to have a logic “low” level.

As described above, the control circuit 30 illustrated in FIG. 2 may be configured to generate the first mat selection signal MS<1>. That is, the control circuit 30 illustrated in FIG. 2 may actually correspond to a first mat selection signal generator or first mat selection signal circuit. Although not shown in the drawings, the control circuit 30 may further include second to fourth mat selection signal generators or circuits for generating the second to fourth mat selection signals MS<2:4>. The second to fourth mat selection signal generators may also be realized to have substantially the same configuration as the control circuit 30 illustrated in FIG. 2. Accordingly, detailed descriptions of the second to fourth mat selection signal generators for generating the second to fourth mat selection signals MS<2:4> will be omitted hereinafter.

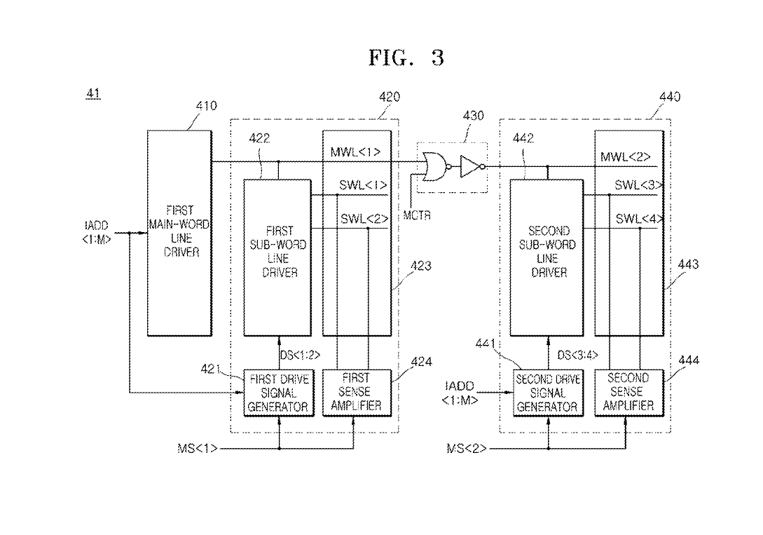

Referring to FIG. 3, the first memory part 41 may include a first main word line driver 410, a first mat 420, a first logic circuit 430, and a second mat 440.

The first main word line driver 410 may activate a first main word line MWL<1> according to a decoded combination of the first to M^{th} internal addresses IADD<1:M>. Although FIG. 3 illustrates an example in which the first main word line driver 410 activates a single main word line, the present disclosure is not limited thereto. For example, in some embodiments, the first main word line driver 410 may be configured to activate a plurality of main word lines according to a combination of the first to M^{th} internal addresses IADD<1:M>.

The first mat 420, which may be connected to the first main word line MWL<1>, may include a first drive signal generator 421, a first sub-word line driver 422, a first memory cell array 423, and a first sense amplifier 424.

The first drive signal generator 421 may receive the first mat selection signal MS<1> to generate first and second drive signals DS<1:2>, one of which is selectively enabled according to a combination of the first to M^{th} internal addresses IADD<1:M>. Although FIG. 3 illustrates an example in which the first drive signal generator 421 is configured to selectively generate any one of the first and second drive signals DS<1:2>, the present disclosure is not limited thereto. For example, in some embodiments, the first drive signal generator 421 may be configured to selectively generate any one of three or more drive signals according to a combination of the first to M^{th} internal addresses IADD<1:M>.

The first sub-word line driver 422 may selectively activate one of a first and second sub-word lines SWL<1:2> in response to the first and second drive signals DS<1:2> if the first main word line MWL<1> is activated.

The first memory cell array 423 may include a plurality of memory cells connected to the first and second sub-word lines SW<1:2>.

The first sense amplifier 424 may sense and amplify data of the memory cells connected to the first and second sub-word lines SW<1:2> in response to the first mat selection signal MS<1>. According to FIG. 3, the first sense amplifier 424 is directly connected to the first and second sub-word lines SW<1:2> for ease and convenience in explanation. However, the first sense amplifier 424 may actually be connected to the plurality of memory cells connected to the first and second sub-word lines SW<1:2> to sense and amplify the data stored in the plurality of memory cells.

The first logic circuit 430 may activate a second main word line MWL<2> in response to a signal of the first main word line MWL<1> and the mat control signal MCTR. The first logic circuit 430 may activate the second main word line MWL<2> so that the second main word line MWL<2> has a logic “low” level if the first main word line MWL<1> is activated to have a logic “low” level and the mat control signal MCTR is disabled to have a logic “low” level. The first logic circuit 430 may inactivate the second main word line MWL<2> if the mat control signal MCTR is enabled to have a logic “high” level.

The second mat 440, which may be connected to the second the second main word line MWL<2>, may include a second drive signal generator 441, a second sub-word line driver 442, a second memory cell array 443, and a second sense amplifier 444.

The second drive signal generator 441 may receive the second mat selection signal MS<2> to generate third and fourth drive signals DS<3:4>, one of which is selectively enabled according to a combination of the first to M^{th} internal addresses IADD<1:M>. Although FIG. 3 illustrates an example in which the second drive signal generator 441 is configured to selectively generate any one of the third and fourth drive signals DS<3:4>, the present disclosure is not limited thereto. For example, in some embodiments, the second drive signal generator 441 may be configured to selectively generate any one of three or more drive signals according to a combination of the first to M^{th} internal addresses IADD<1:M>.

The second sub-word line driver 442 may selectively activate one of a third and fourth sub-word lines SWL<3:4> in response to the third and fourth drive signals DS<3:4> if the second main word line MWL<2> is activated.

The second memory cell array 443 may include a plurality of memory cells connected to the third and fourth sub-word lines SW<3:4>.

The second sense amplifier 444 may sense and amplify data of the memory cells connected to the third and fourth sub-word lines SW<3:4> in response to the second mat selection signal MS<2>. According to FIG. 3, the second sense amplifier 444 is directly connected to the third and fourth sub-word lines SW<3:4> for the purpose of ease and convenience in explanation. However, the second sense amplifier 444 may actually be connected to the plurality of memory cells connected to the third and fourth sub-word lines SW<3:4> to sense and amplify the data stored in the plurality of memory cells.

The second memory part 42 may have substantially the same configuration and operation as the first memory part 41. Thus, detailed descriptions of the second memory part 42 will be omitted hereinafter.

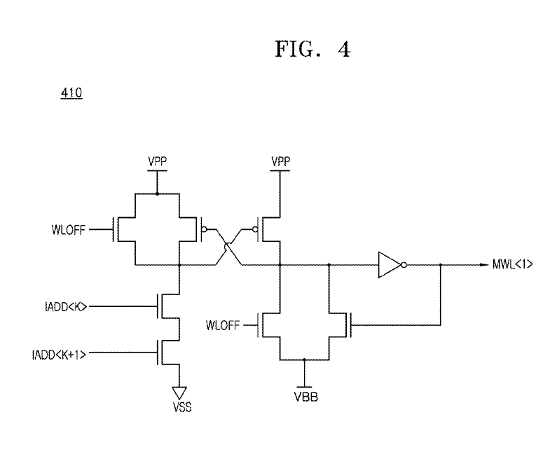

An operation of the first main word line driver 410 will be described more fully hereinafter with reference to FIG. 4.

The first main word line driver 410 may drive the first main word line MWL<1> to a logic “high” level in response to a word line off signal WLOFF which is enabled if the semiconductor system is out of active operation and the refresh operation. That is, the first main word line driver 410 may inactivate the first main word line MWL<1> if the semiconductor system is out of the active operation and the refresh operation. The word line off signal WLOFF may be set to be enabled to have a logic “high” level in a power-down mode and a power-up mode that are out of the active operation and the refresh operation. In addition, a high voltage VPP illustrated in FIG. 4 may be a pumped voltage which is higher than a power supply voltage supplied to the semiconductor devices 1 and 2 of FIG. 1, and a low voltage VBB illustrated in FIG. 4 may be a pumped voltage which is lower than the ground voltage VSS supplied to the semiconductor devices 1 and 2 of FIG. 1.

The first main word line driver 410 may drive the first main word line MWL<1> to a logic “low” level if internal addresses IADD<K> and IADD<K+1> among the first to M^{th} internal addresses IADD<1:M> are generated to activate the first main word line MWL<1> during the active operation and the refresh operation. That is, the first main word line driver 410 may activate the first main word line MWL<1> if the internal addresses IADD<K> and IADD<K+1> for activating the first main word line MWL<1> are generated during the active operation and the refresh operation. A bit number “K” of the internal addresses IADD<K> and IADD<K+1> for activating the first main word line MWL<1> may be set to be a natural number which is less than the natural number “M” of the first to M^{th} internal addresses IADD<1:M>, and the internal addresses IADD<K> and IADD<K+1> may be set to be one or more bits among the first to M^{th} internal addresses IADD<1:M>.

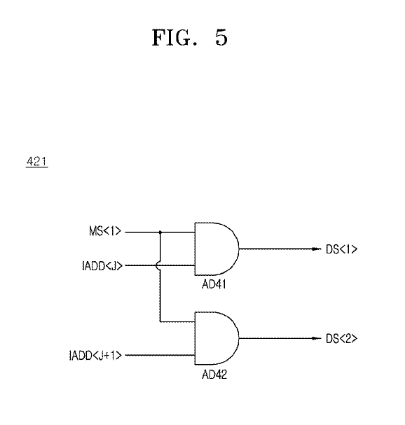

An operation of the first drive signal generator 421 will be described more fully hereinafter with reference to FIG. 5.

The first drive signal generator 421 may include an AND gate AD41 and an AND gate AD42.

The AND gate AD41 may generate the first drive signal DS<1> which is enabled to have a logic “high” level if the first mat selection signal MS<1> is enabled to have a logic “high” level and an internal address IADD<J> among the first to M^{th} internal addresses IADD<1:M> is generated to activate the first sub-word line SWL<1>. A bit number “3” of the internal address IADD<J> for generating the first drive signal DS<1> may be set to a natural number which is less than the natural number “M” of the first to M^{th} internal addresses IADD<1:M>, and the internal address IADD<J> may be set to be one or more bits among the first to M^{th} internal addresses IADD<1: M>.

The AND gate AD42 may generate the second drive signal DS<2> which is enabled to have a logic “high” level if the first mat selection signal MS<1> is enabled to have a logic “high” level and an internal address IADD<J+1> among the first to M^{th} internal addresses IADD<1:M> is generated to activate the second sub-word line SWL<2>. A bit number “J+1” of the internal address IADD<J+1> for generating the second drive signal DS<2> may be set to a natural number which is less than the natural number “M” of the first to M^{th} internal addresses IADD<1:M>, and the internal address IADD<J+1> may be set to be one or more bits among the first to M^{th} internal addresses IADD<1:M>.

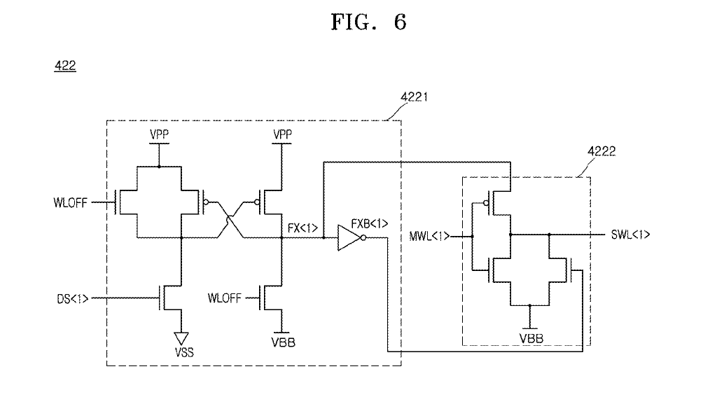

Referring to FIG. 6, the first sub-word line driver 422 may include a selection signal generator 4221 and a driver 4222.

The selection signal generator 4221 may drive a first selection signal FX<1> to the low voltage VBB and may drive a first inverted selection signal FXB<1> to a logic “high” level, if the word line off signal WLOFF is enabled to have a logic “high” level.

The selection signal generator 4221 may drive the first selection signal FX<1> to a high voltage VPP and may drive the first inverted selection signal FXB<1> to a logic “low” level, if the first drive signal DS<1> is enabled to have a logic “high” level.

The driver 4222 may drive the first sub-word line SWL<1> to a low voltage VBB if the first inverted selection signal FXB<1> is generated to have a logic “high” level. That is, the driver 4222 may inactivate the first sub-word line SWL<1> if the first inverted selection signal FXB<1> is generated to have a logic “high” level.

The driver 4222 may drive the first sub-word line SWL<1> to the high voltage VPP if the first selection signal FX<1> is generated to have the high voltage VPP and the first main word line MWL<1> is activated to have a logic “low” level. That is, the driver 4222 may activate the first sub-word line SWL<1> if the first selection signal FX<1> is generated to have the high voltage VPP and the first main word line MWL<1> is activated to have a logic “low” level.

The driver 4222 may drive the first sub-word line SWL<1> to the low voltage VBB if the first main word line MWL<1> is inactivated to have a logic “high” level. That is, the driver 4222 may inactivate the first sub-word line SWL<1> if the first main word line MWL<1> is inactivated to have a logic “high” level.

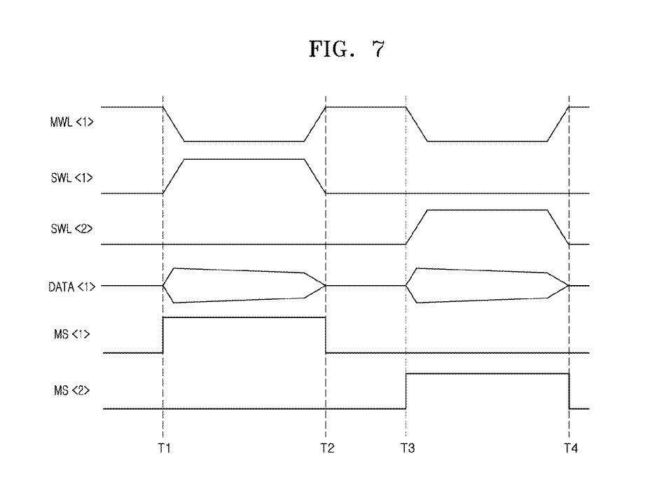

An operation of the semiconductor system having the aforementioned configuration will be described hereinafter with reference to FIG. 7 in conjunction with an example in which the second mat 440 of the first memory part 41 is activated after the first mat 420 of the first memory part 41 is activated.

First, an operation for activating the first mat 420 of the first memory part 41 from a time point “T1” until a time point “T2” will be described hereinafter.

At time point “T1”, the control circuit 30 may receive the first row address RADD<1> having a logic “high” level, the second row address RADD<2> having a logic “low” level, the first column address CADD<1> having a logic “high” level, and the second column address CADD<2> having a logic “low” level to generate the first mat selection signal MS<1> having a logic “high” level and the second mat selection signal MS<2> having a logic “low” level. In such a case, the third and fourth mat selection signals MS<3:4> may be generated to have a logic “low” level.

The first main word line driver 410 may drive the first main word line MWL<1> to a logic “low” level in response to the first to M^{th} internal addresses IADD<1:M>. That is, the first main word line driver 410 may activate the first main word line MWL<1>.

The first drive signal generator 421 may generate the first drive signal DS<1> having a logic “high” level and the second drive signal DS<2> having a logic “low” level in response to the first mat selection signal MS<1> having a logic “high” level and the first to M^{th} internal addresses IADD<1:M>.

The first sub-word line driver 422 may drive the first sub-word line SWL<1> to a logic “high” level and may drive the second sub-word line SWL<2> to a logic “low” level, in response to the first main word line MWL<1> having a logic “low” level and the first drive signal DS<1> having a logic “high” level. That is, the first sub-word line driver 422 may activate the first sub-word line SWL<1>.

The first sense amplifier 424 may sense and amplify the data of the memory cells connected to the first sub-word line SWL<1>. Data DATA<1> illustrated in FIG. 7 corresponds to data stored in the memory cells.

Next, an operation for activating the second mat 440 of the first memory part 41 from a time point “T3” until a time point “T4” will be described hereinafter.

At time point “T3”, the control circuit 30 may receive the first row address RADD<1> having a logic “high” level, the second row address RADD<2> having a logic “low” level, the first column address CADD<1> having a logic “low” level, and the second column address CADD<2> having a logic “high” level to generate the first mat selection signal MS<1> having a logic “low” level and the second mat selection signal MS<2> having a logic “high” level. In such a case, the third and fourth mat selection signals MS<3:4> may be generated to have a logic “low” level.

The first main word line driver 410 may drive the first main word line MWL<1> to a logic “low” level in response to the first to M^{th} internal addresses IADD<1:M>. That is, the first main word line driver 410 may activate the first main word line MWL<1>.

The first drive signal generator 421 may generate the first drive signal DS<1> having a logic “low” level and the second drive signal DS<2> having a logic “high” level in response to the second mat selection signal MS<2> having a logic “high” level and the first to M^{th} internal addresses IADD<1:M>.

The first sub-word line driver 422 may drive the first sub-word line SWL<1> to a logic “low” level and may drive the second sub-word line SWL<2> to a logic “high” level, in response to the first main word line MWL<1> having a logic “low” level and the first drive signal DS<1> having a logic “high” level. That is, the first sub-word line driver 422 may activate the second sub-word line SWL<2>.

The first sense amplifier 424 may sense and amplify the data of the memory cells connected to the second sub-word line SWL<2>.

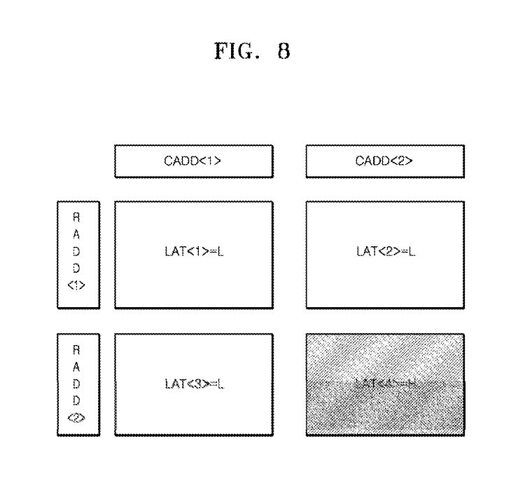

Operations of the semiconductor system having the aforementioned configuration will be described hereinafter with reference to FIGS. 8, 9, and 10 in conjunction with an example in which the self-refresh operation is executed after the active operation.

Referring to FIG. 8, during the active operation, if the first row address RADD<1>, the second row address RADD<2>, the first column address CADD<1>, and the second column address CADD<2> are generated to have a logic “low” level, a logic “high” level, a logic “low” level, and a logic “high” level, respectively, the first to third latch signals LAT<1:3> may be generated to have a logic “low” level and the fourth latch signal LAT<4> may be generated to have a logic “high” level. In addition, the first to fourth latch signals LAT<1:4> may be stored in the control circuit 30 of the semiconductor system.

That is, the fourth mat (not shown) of the second memory part 42 may be activated to execute the active operation.

The first to fourth latch signals LAT<1:4> may include stored information on the location of the mats which are individually activated, and generation of the fourth latch signal LAT<4> having a logic “high” level may mean that the fourth mat (not shown) of the second memory part 42 is activated. In such a case, generation of the first to third latch signals LAT<1:3> having a logic “low” level may mean that the first and second mats 420 and 440 of the first memory part 41 and a third mat (not shown) of the second memory part 42 are not activated.

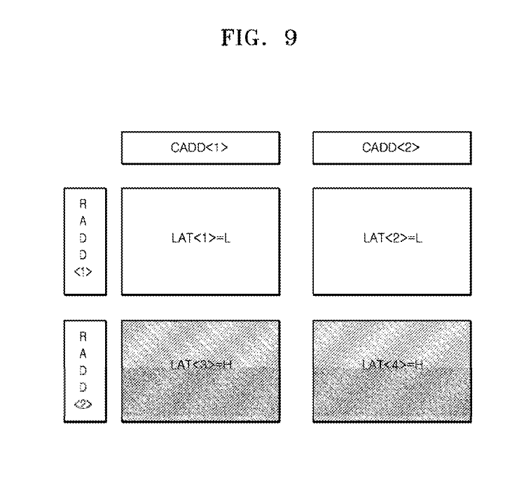

Referring to FIG. 9, during the active operation, if the first row address RADD<1>, the second row address RADD<2>, the first column address CADD<1>, and the second column address CADD<2> are generated to have a logic “low” level, a logic “high” level, a logic “high” level and a logic “low” level, respectively, the first and second latch signals LAT<1:2> may be generated to have a logic “low” level and the third and fourth latch signals LAT<3:4> may be generated to have a logic “high” level. In addition, the first to fourth latch signals LAT<1:4> may be stored in the control circuit 30 of the semiconductor system.

That is, the third mat (not shown) of the second memory part 42 may be activated to execute the active operation.

Generation of the first and second latch signals LAT<1:2> having a logic “low” level may mean that the first and second mats 420 and 440 of the first memory part 41 is inactivated. In addition, generation of the fourth latch signal LAT4<4> having a logic “high” level may mean that the fourth latch signal LAT4<4> is stored and generated, as described with reference to FIG. 8.

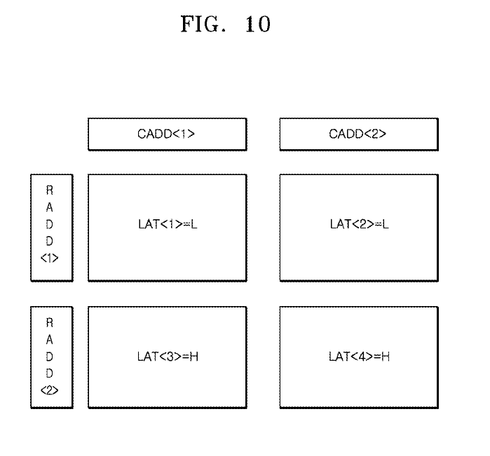

The self-refresh operation executed after the active operation will be described hereinafter with reference to FIG. 10.

First, if the first row address RADD<1> is generated to have a logic “high” level and the first and second column addresses CADD<1:2> are sequentially generated to have a logic “high” level during the self-refresh operation, the first and second mats 420 and 440 of the first memory part 41, not selected based on location information of the mats 420 and 440, may be inactivated to not execute the refresh operation because the first and second latch signals LAT<1:2> having a logic “low” level are stored.

Next, if the second row address RADD<2> is generated to have a logic “high” level and the first and second column addresses CADD<1:2> are sequentially generated to have a logic “high” level during the self-refresh operation, the third and fourth mats (not shown) of the second memory part 42 may be activated and execute the refresh operation because the third and fourth latch signals LAT<3:4> having a logic “high” level are stored.

As described above, a semiconductor system according to an embodiment may store location information of word lines activated in an active mode and may execute a refresh operation relating to only word lines activated according to the location information of the word lines in a refresh mode. Thus, power consumption of the semiconductor system may be reduced.

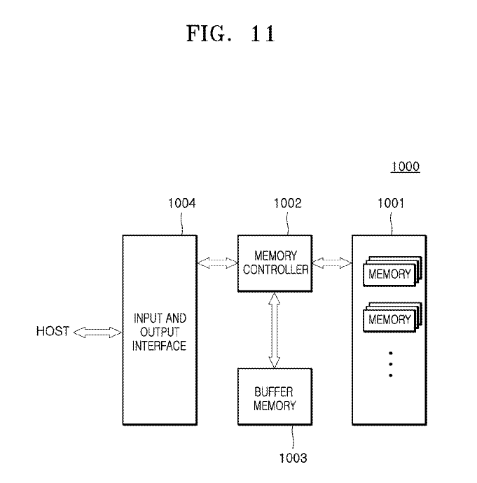

The second semiconductor device or the semiconductor system described with reference to FIGS. 1 to 10 may be applied to an electronic system that includes a memory system, a graphic system, a computing system, a mobile system, or the like. For example, as illustrated in FIG. 11, an electronic system 1000 according an embodiment may include a data storage unit 1001, a memory controller 1002, a buffer memory 1003, and an I/O interface 1004.

The data storage unit 1001 may store data which is outputted from the memory controller 1002 or may read and output the stored data to the memory controller 1002, according to a control signal generated from the memory controller 1002. The data storage unit 1001 may include the second semiconductor device 2 illustrated in FIG. 1. The data storage unit 1001 may also include a nonvolatile memory that can retain stored data even when its power supply is interrupted. The nonvolatile memory may be a flash memory such as a NOR-type flash memory or a NAND-type flash memory, a phase change random access memory (PRAM), a resistive random access memory (RRAM), a spin transfer torque random access memory (STTRAM), a magnetic random access memory (MRAM), or the like.

The memory controller 1002 may receive a command outputted from an external device (e.g., a host device) through the I/O interface 1004 and may decode the command outputted from the host device to control an operation for inputting data into the data storage unit 1001 or the buffer memory 1003, or for outputting the data stored in the data storage unit 1001 or the buffer memory 1003. The memory controller 1002 may include the first semiconductor device 1 illustrated in FIG. 1. Although FIG. 11 illustrates the memory controller 1002 as a single block, the memory controller 1002 may include one controller for controlling the data storage unit 1001 comprised of a nonvolatile memory and another controller for controlling the buffer memory 1003 comprised of a volatile memory.

The buffer memory 1003 may temporarily store data processed by the memory controller 1002. That is, the buffer memory 1003 may temporarily store the data outputted from or inputted to the data storage unit 1001. The buffer memory 1003 may store the data, outputted from the memory controller 1002, according to a control signal. The buffer memory 1003 may read and output the stored data to the memory controller 1002. The buffer memory 1003 may include a volatile memory such as a dynamic random access memory (DRAM), a mobile DRAM, or a static random access memory (SRAM).

The I/O interface 1004 may physically and electrically connect the memory controller 1002 to the external device (i.e., the host). Thus, the memory controller 1002 may receive control signals and data supplied from the external device (i.e., the host) through the I/O interface 1004 and may output the data generated from the memory controller 1002 to the external device (i.e., the host) through the I/O interface 1004. That is, the electronic system 1000 may communicate with the host through the I/O interface 1004. The I/O interface 1004 may include any one of various interface protocols such as a universal serial bus (USB), a multi-media card (MMC), a peripheral component interconnect-express (PCI-E), a serial attached SCSI (SAS), a serial AT attachment (SATA), a parallel AT attachment (PATA), a small computer system interface (SCSI), an enhanced small device interface (ESDI), and an integrated drive electronics (IDE).

The electronic system 1000 may be used as an auxiliary storage device of the host or an external storage device. The electronic system 1000 may include a solid state disk (SSD), a USB memory, a secure digital (SD) card, a mini secure digital (mSD) card, a micro secure digital (micro SD) card, a secure digital high capacity (SDHC) card, a memory stick card, a smart media (SM) card, a multi-media card (MMC), an embedded multi-media card (eMMC), a compact flash (CF) card, or the like.

1. A semiconductor system comprising:
a semiconductor device suitable for executing an active operation according to a combination of command and address (command/address) signals to store location information of mats which are individually activated and suitable for executing a refresh operation according to a combination of the command/address signals to individually activate the mats included in a memory part according to the location information stored in the semiconductor device in response to a mat control signal.

2. The semiconductor system of claim 1, wherein the mat control signal is enabled to selectively activate the mats included in the memory part.

3. The semiconductor system of claim 1, wherein the semiconductor device inactivates the mats of the memory part, which are not selected according to the location information during the refresh operation.

4. The semiconductor system of claim 1, wherein the semiconductor device includes:
an address decoder suitable for decoding the command/address signals to generate a row address, a column address and an internal address;
a control circuit suitable for receiving the row address and the column address to store the location information therein in response to an active signal or an internal refresh signal, suitable for generating a mat selection signal from the location information, and suitable for outputting the column address as the mat selection signal in response to an auto-refresh signal and the row address; and
an internal circuit including a first memory part and a second memory part, one of which is selectively activated in response to the mat control signal and the mat selection signal.

5. The semiconductor system of claim 4,
wherein the row address includes a first row address and a second row address;
wherein the column address includes a first column address and a second column address;
wherein the mat selection signal includes first to fourth mat selection signals; and
wherein the control circuit includes:
a first mat selection signal generator suitable for storing the first column address as a first latch signal and outputting the first column address as the first mat selection signal in response to the active signal and the first row address, suitable for outputting the first latch signal as the first mat selection signal in response to the internal refresh signal, and suitable for outputting the first column address as the first mat selection signal in response to the auto-refresh signal and the first row address;
a second mat selection signal generator suitable for storing the second column address as a second latch signal and outputting the second column address as the second mat selection signal in response to the active signal and the first row address, suitable for outputting the second latch signal as the second mat selection signal in response to the internal refresh signal, and suitable for outputting the second column address as the second mat selection signal in response to the auto-refresh signal and the second row address;
a third mat selection signal generator suitable for storing the first column address as a third latch signal and outputting the first column address as the third mat selection signal in response to the active signal and the second row address, suitable for outputting the third latch signal as the third mat selection signal in response to the internal refresh signal, and suitable for outputting the first column address as the third mat selection signal in response to the auto-refresh signal and the second row address; and
a fourth mat selection signal generator suitable for storing the second column address as a fourth latch signal and outputting the second column address as the fourth mat selection signal in response to the active signal and the second row address, suitable for outputting the fourth latch signal as the fourth mat selection signal in response to the internal refresh signal, and suitable for outputting the second column address as the fourth mat selection signal in response to the auto-refresh signal and the second row address.

6. The semiconductor system of claim 4, wherein the location information includes the first to fourth latch signals.

7. The semiconductor system of claim 4,
wherein the mat selection signal includes first to fourth mat selection signals; and
wherein the first memory part includes:
a first main word line driver suitable for decoding the internal address to activate a first main word line;
a first mat, connected to the first main word line, suitable for activating first and second sub-word lines in response to the first mat selection signal;
a first logic circuit suitable for activating a second main word line in response to a signal of the first main word line and the mat control signal; and
a second mat, connected to the second main word line, suitable for activating third and fourth sub-word lines in response to the second mat selection signal.

8. The semiconductor system of claim 7, wherein the first mat includes:
a first drive signal generator suitable for receiving the first mat selection signal to generate first and second drive signals, one of which is selectively enabled according to a combination of the internal address;
a first sub-word line driver suitable for selectively activating one of the first and second sub-word lines in response to the first and second drive signals if the first main word line is activated;
a first memory cell array including a plurality of memory cells connected to the first and second sub-word lines; and
a first sense amplifier suitable for sensing and amplifying data of the plurality of memory cells connected to the first and second sub-word lines in response to the first mat selection signal.

9. The semiconductor system of claim 7, wherein the second mat includes:
a second drive signal generator suitable for receiving the second mat selection signal to generate third and fourth drive signals, one of which is selectively enabled according to a combination of the internal address;
a second sub-word line driver suitable for selectively activating one of the third and fourth sub-word lines in response to the third and fourth drive signals if the second main word line is activated;
a second memory cell array including a plurality of memory cells connected to the third and fourth sub-word lines; and
a second sense amplifier suitable for sensing and amplifying data of the plurality of memory cells connected to the third and fourth sub-word lines in response to the second mat selection signal.

10. The semiconductor system of claim 4,
wherein the mat selection signal includes first to fourth mat selection signals; and
wherein the second memory part includes:
a third main word line driver suitable for decoding the internal address to activate a third main word line;
a third mat, connected to the third main word line, suitable for activating fifth and sixth sub-word lines in response to the third mat selection signal;
a second logic circuit suitable for activating a fourth main word line in response to a signal of the third main word line and the mat control signal; and
a fourth mat, connected to the fourth main word line, suitable for activating seventh and eighth sub-word lines in response to the fourth mat selection signal.

11. The semiconductor system of claim 10, wherein the third mat includes:
a third drive signal generator suitable for receiving the third mat selection signal to generate fifth and sixth drive signals, one of which is selectively enabled according to a combination of the internal address;
a third sub-word line driver suitable for selectively activating one of the fifth and sixth sub-word lines in response to the fifth and sixth drive signals if the third main word line is activated;
a third memory cell array including a plurality of memory cells connected to the fifth and sixth sub-word lines; and
a third sense amplifier suitable for sensing and amplifying data of the plurality of memory cells connected to the fifth and sixth sub-word lines in response to the third mat selection signal.

12. The semiconductor system of claim 10, wherein the fourth mat includes:
a fourth drive signal generator suitable for receiving the fourth mat selection signal to generate seventh and eighth drive signals, one of which is selectively enabled according to a combination of the internal address;
a fourth sub-word line driver suitable for selectively activating one of the seventh and eighth sub-word lines in response to the seventh and eighth drive signals if the fourth main word line is activated;
a fourth memory cell array including a plurality of memory cells connected to the seventh and eighth sub-word lines; and
a fourth sense amplifier suitable for sensing and amplifying data of the plurality of memory cells connected to the seventh and eighth sub-word lines in response to the fourth mat selection signal.

13. A semiconductor device comprising:
a command decoder suitable for decoding command and address (command/address) signals to generate an active signal enabled to execute an active operation and to generate an auto-refresh signal and an internal refresh signal enabled to execute a refresh operation;
an address decoder suitable for decoding the command/address signals to generate a row address, a column address and an internal address;
a control circuit suitable for receiving the row address and the column address to store location information therein in response to the active signal or the internal refresh signal, suitable for generating a mat selection signal from the location information, and suitable for outputting the column address as the mat selection signal in response to the auto-refresh signal and the row address; and
an internal circuit including a first memory part and a second memory part, one of which is selectively activated in response to a mat control signal and the mat selection signal.

14. The semiconductor device of claim 13, wherein the mat control signal is enabled to selectively activate a plurality of mats included in the first and second memory parts.

15. The semiconductor device of claim 13, wherein the mats of the first and second memory parts, which are not selected according to the location information during the refresh operation, are inactivated.

16. The semiconductor device of claim 13,
wherein the row address includes a first row address and a second row address;
wherein the column address includes a first column address and a second column address;
wherein the mat selection signal includes first to fourth mat selection signals; and
wherein the control circuit includes:
a first mat selection signal generator suitable for storing the first column address as a first latch signal and outputting the first column address as the first mat selection signal in response to the active signal and the first row address, suitable for outputting the first latch signal as the first mat selection signal in response to the internal refresh signal, and suitable for outputting the first column address as the first mat selection signal in response to the auto-refresh signal and the first row address;
a second mat selection signal generator suitable for storing the second column address as a second latch signal and outputting the second column address as the second mat selection signal in response to the active signal and the first row address, suitable for outputting the second latch signal as the second mat selection signal in response to the internal refresh signal, and suitable for outputting the second column address as the second mat selection signal in response to the auto-refresh signal and the second row address;
a third mat selection signal generator suitable for storing the first column address as a third latch signal and outputting the first column address as the third mat selection signal in response to the active signal and the second row address, suitable for outputting the third latch signal as the third mat selection signal in response to the internal refresh signal, and suitable for outputting the first column address as the third mat selection signal in response to the auto-refresh signal and the second row address; and
a fourth mat selection signal generator suitable for storing the second column address as a fourth latch signal and outputting the second column address as the fourth mat selection signal in response to the active signal and the second row address, suitable for outputting the fourth latch signal as the fourth mat selection signal in response to the internal refresh signal, and suitable for outputting the second column address as the fourth mat selection signal in response to the auto-refresh signal and the second row address.

17. The semiconductor device of claim 16, wherein the location information includes the first to fourth latch signals.

18. The semiconductor device of claim 13,
wherein the mat selection signal includes first to fourth mat selection signals; and
wherein the first memory part includes:
a first main word line driver suitable for decoding the internal address to activate a first main word line;
a first mat, connected to the first main word line, suitable for activating first and second sub-word lines in response to the first mat selection signal;
a first logic circuit suitable for activating a second main word line in response to a signal of the first main word line and the mat control signal; and
a second mat, connected to the second main word line, suitable for activating third and fourth sub-word lines in response to the second mat selection signal.

19. The semiconductor device of claim 18, wherein the first mat includes:
a first drive signal generator suitable for receiving the first mat selection signal to generate first and second drive signals, one of which is selectively enabled according to a combination of the internal address;
a first sub-word line driver suitable for selectively activating one of the first and second sub-word lines in response to the first and second drive signals if the first main word line is activated;
a first memory cell array including a plurality of memory cells connected to the first and second sub-word lines; and
a first sense amplifier suitable for sensing and amplifying data of the plurality of memory cells connected to the first and second sub-word lines in response to the first mat selection signal.

20. The semiconductor device of claim 18, wherein the second mat includes:
a second drive signal generator suitable for receiving the second mat selection signal to generate third and fourth drive signals, one of which is selectively enabled according to a combination of the internal address;
a second sub-word line driver suitable for selectively activating one of the third and fourth sub-word lines in response to the third and fourth drive signals if the second main word line is activated;
a second memory cell array including a plurality of memory cells connected to the third and fourth sub-word lines; and
a second sense amplifier suitable for sensing and amplifying data of the plurality of memory cells connected to the third and fourth sub-word lines in response to the second mat selection signal.

21. The semiconductor device of claim 13,
wherein the mat selection signal includes first to fourth mat selection signals; and
wherein the second memory part includes:
a third main word line driver suitable for decoding the internal address to activate a third main word line;
a third mat, connected to the third main word line, suitable for activating fifth and sixth sub-word lines in response to the third mat selection signal;
a second logic circuit suitable for activating a fourth main word line in response to a signal of the third main word line and the mat control signal; and
a fourth mat, connected to the fourth main word line, suitable for activating seventh and eighth sub-word lines in response to the fourth mat selection signal.

22. The semiconductor device of claim 21, wherein the third mat includes:
a third drive signal generator suitable for receiving the third mat selection signal to generate fifth and sixth drive signals, one of which is selectively enabled according to a combination of the internal address;
a third sub-word line driver suitable for selectively activating one of the fifth and sixth sub-word lines in response to the fifth and sixth drive signals if the third main word line is activated;
a third memory cell array including a plurality of memory cells connected to the fifth and sixth sub-word lines; and
a third sense amplifier suitable for sensing and amplifying data of the plurality of memory cells connected to the fifth and sixth sub-word lines in response to the third mat selection signal.

23. The semiconductor device of claim 21, wherein the fourth mat includes:
a fourth drive signal generator suitable for receiving the fourth mat selection signal to generate seventh and eighth drive signals, one of which is selectively enabled according to a combination of the internal address;
a fourth sub-word line driver suitable for selectively activating one of the seventh and eighth sub-word lines in response to the seventh and eighth drive signals if the fourth main word line is activated;
a fourth memory cell array including a plurality of memory cells connected to the seventh and eighth sub-word lines; and
a fourth sense amplifier suitable for sensing and amplifying data of the plurality of memory cells connected to the seventh and eighth sub-word lines in response to the fourth mat selection signal.
